(19) United States
(12) Patent Application Publication
(10) Pub. No.: US 2010/0097244 A1
(43) Pub. Date: Apr. 22, 2010

(54) MULTIPURPOSE KEYBOARD

(75) Inventor: SHU XIE, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO.LTD., Shenzhen City (TW); HON HAI PRECISION INDUSTRY CO., LTD., Tu-Cheng (TW)

(21) Appl. No.: 12/266,565

(22) Filed: Nov. 7, 2008

(30) Foreign Application Priority Data
Oct. 17, 2008 (CN) 200810304984.7

(51) Int. Cl. H03M 11/00

(52) U.S. Cl. 341/22

(57) ABSTRACT

A keyboard includes a numerical keypad, a switch key, a switch module, a telephone interface, a keyboard control chip, and a telephone module. The numerical keypad is configured for inputting numerical data to a host computer and for inputting telephone numbers. The switch module is connected to the numerical keypad and the switch key, and configured for controlling the numerical keypad to input numerical data or input telephone numbers according to a status of the switch key. The telephone interface is configured for receiving a telephone signal. The keyboard control chip is connected to the switch module and the numerical keypad. The telephone module is connected to the telephone interface and the switch module.

### BACKGROUND

1. Technical Field

The present disclosure relates to keyboards and, particularly, to a multipurpose keyboard.

2. Description of Related Art

Contemporary keyboards are single purpose devices merely serving as input devices. Designers of keyboards often focus on improving keys of the keyboards rather than inventing other uses for the keyboards.

What is needed, is a multipurpose keyboard.

### BRIEF DESCRIPTION OF THE DRAWINGS

FIG. 1 is a top plan view of a first embodiment of a keyboard.

FIG. 2 is a rear elevational view of the keyboard of FIG. 1.

FIG. 3 is a right-side, elevational view of the keyboard of FIG. 1.

FIG. 4 is a functional block diagram of the keyboard of FIG. 1.

FIG. 5 is a functional block diagram of a second embodiment of a keyboard.

### DETAILED DESCRIPTION

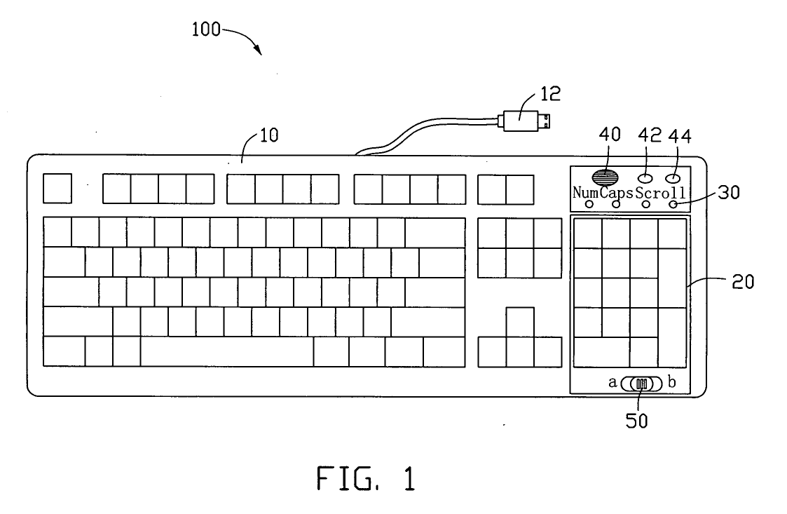

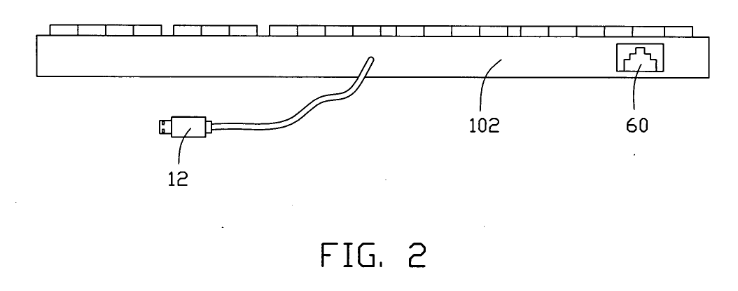

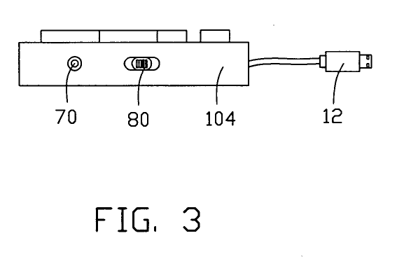

Referring to FIGS. 1 to 3, a first embodiment of a keyboard 100 of the present disclosure is shown. The keyboard 100 may be connected to a computer for inputting various data to the computer. In one embodiment, the keyboard 100 includes a USB plug 12, a main keypad 10, a numerical keypad 20, an indication apparatus such as an indicator 30, an audible apparatus such as a buzzer 40, a switch key 50, a redial key 42, a receive/stop key 44, a telephone interface 60, an headset interface 70, and a volume key 80.

The switch key 50 shifts between an “a” position and a “b” position and is configured to control the numerical keypad 20 to input numerical data to the computer or input telephone numbers. The indicator 30 is configured to indicate work state of telephone communication. The buzzer 40 is configured to buzz when a telephone call is received. The redial key is configured to redial last phone number entered. The receive/stop key 44 is configured to accept incoming telephone calls and disconnect from calls when a user is finished. The telephone interface 60 is configured to connect to a telephone line, for receiving a telephone signal. The headset interface 70 is configured to receive a telephone headset. The volume key 80 is configured to adjust volume of the buzzer 40.

In one embodiment, the buzzer 40, the redial key 42, and the receive/stop key 44 are mounted on a top of the numerical keypad 20. The redial key 42 is located between the buzzer 40 and the receive/stop key 44. The indicator 30 is located between the numerical keypad 20 and the receive/stop key 44, in alignment with a “Num” indicator, a “Caps” indicator, and a “Scroll” indicator on the numerical keypad 20. The switch key 50 is mounted on a bottom of the numerical keypad 20. The telephone interface 60 and the USB plug 12 are set on a rear sidewall 102 of the keyboard 100. The headset interface 70 and the volume key 80 are set on a right sidewall 104 of the keyboard 100.

The indicator 30, the buzzer 40, the redial key 42, the receive/stop key 44, the switch key 50, the telephone interface 60, the headset interface 70, and the volume key 80 can be arranged at other suitable locations on the keyboard 100 according to need.

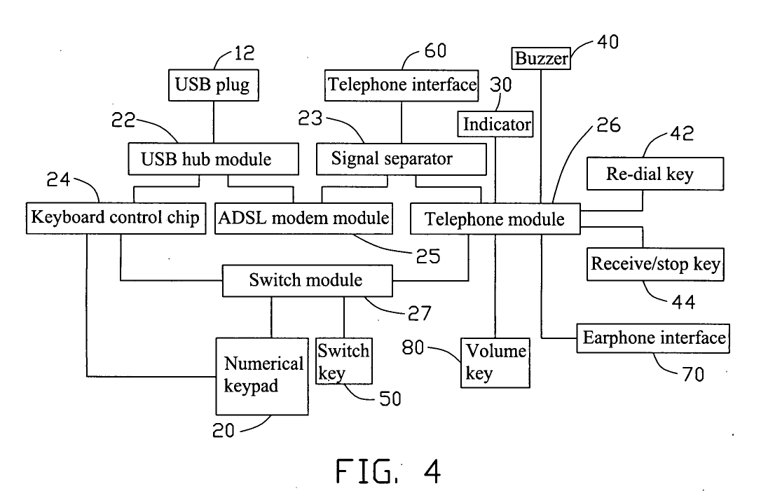

Referring to FIG. 4, the keyboard 100 further includes a USB hub module 22, a signal separator 23, a keyboard control chip 24, an asymmetric digital subscriber line (ADSL) modem module 25, a telephone module 26, and a switch module 27.

An output terminal of the USB hub module 22 is connected to a USB interface of a host computer via the USB plug 12, for receiving power from the computer and providing the power to the keyboard 100 and transmitting data between the computer and the keyboard 100. Two input terminals of the USB hub 22 are respectively connected to the keyboard control chip 24 and the ADSL modem module 25. The keyboard control chip 24 is connected to the switch module 27 and the numerical keypad 20. An output terminal of the signal separator 23 is connected to the telephone line via the telephone interface 60. Two output terminals of the signal separator 23 are respectively connected to the ADSL modem module 25 and the telephone module 26. The signal separator 23 is configured to separate network connection from telephone connection, The telephone module 26 is connected to the switch module 27, the headset interface 70, the volume key 80, the indicator 30, the buzzer 40, the redial key 42, and the receive/stop key 44. The switch module 27 is connected to the numerical keypad 20 and the switch key 50.

When the telephone line is connected to the telephone interface 60, and the computer is booted up, the keyboard 100 can be operated. When the switch key 50 is placed on “a”, the switch module 27 outputs a control signal to the numerical keypad 20, for placing the numerical keypad 20 in computer input mode. In this mode, when the numerical keypad 20 receives input, it is sent to the keyboard control chip 24 which then sends the input to the computer via the USB hub module 22. The telephone signal is provided to the telephone module 26 and the ADSL modem module 25 via the signal separator 23.

The computer has access to the internet through the ADSL modem module 25 and access to a telephone network, for receiving telephone calls, through the telephone module 26. When there is an incoming telephone call, the buzzer 40 buzzes, and the indicator 30 twinkles, for alerting the user. The user may then receive the call by pressing the receive/stop key 44 and connecting an earphone to the telephone interface 70. During communication, the indicator 30 remains steadily lit for indicating a normal state of telephone communication. When done, the user disconnects from the call by pressing the receive/stop key 44 again, and the indicator 30 turns off.

When the switch key 50 is placed in the “b” position, the switch module 27 outputs the control signal to the numerical keypad 20 for controlling the numerical keypad 20 to be in a telephone number input mode. The telephone signal is provided to the telephone module 26 and the ADSL modem module 25 via the signal separator 23. The computer still has access to the Internet through the ADSL modem module 25 and the telephone network through the telephone module 26. User can then dial a telephone number by pressing keys of the numerical keypad 20 and press the receive/stop key 44 to place a call. To call last number dialed rather than inputting the phone number again, the user need only press the redial key 42. Volume of the buzzer 40 can be adjusted by adjusting the volume key 80. During communication, the indicator 30 remains steadily lit for indicating a normal state of the communication. The user may disconnect from the telephone call by pressing the receive/stop key 44 again, and the indicator 30 turns off. The keyboard 100 in addition to being an input device of the computer also functions as a telephone. The USB hub module 22, the signal separator 23, and the ADSL modem module 25 can be deleted according to need.

While the computer has access to the telephone network, the keyboard 100 may still be used as a telephone to receive and place calls by having the switch key 50 in the “b” position, and operation of the phone function is same as described above.

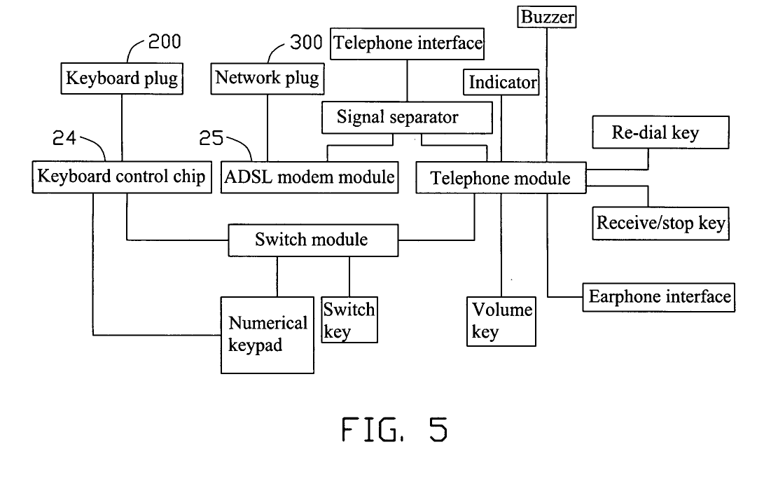

Referring to FIG. 5, a second embodiment of the keyboard 100 is shown. In the second embodiment, the USB hub module 22 and the USB plug 12 as shown in FIG. 4 are deleted. A network plug 300 and a keyboard plug 200 are added. The keyboard control chip 24 is connected to the keyboard plug 200, and the keyboard plug 200 connects to a keyboard interface of the host computer, for receiving power from the host computer and providing the power to the keyboard 100 and transmitting data between the keyboard 100 and the host computer. The ADSL modem module 25 is connected to the network plug 300, and the network plug 300 connects to a network interface of the host computer. The theory and architecture of the second embodiment of the keyboard is same as the first embodiment of the keyboard. In the second embodiment, the keyboard plug 200 may be other type of keyboard plug, such as a PS/2 plug.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others skilled in the art to utilize the disclosure and various embodiments and with various modifications as are suited to the particular use contemplated. Alternately embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A keyboard comprising:
a numerical keypad configured for inputting numerical data to a host computer and for inputting telephone numbers;
a switch key;
a switch module connected to the numerical keypad and the switch key, and configured for controlling the numerical keypad to input numerical data or input telephone numbers according to a status of the switch key;
a telephone interface configured for receiving a telephone signal;
a keyboard control chip connected to the switch module and the numerical keypad; and
a telephone module connected to the telephone interface and the switch module.

2. The keyboard of claim 1, further comprising a keyboard plug configured for connecting to a keyboard interface of the host computer.

3. The keyboard of claim 2, wherein the keyboard plug is a universal serial bus (USB) plug.

4. The keyboard of claim 3, further comprising a USB hub module, a signal separator, and an ADSL modem module, wherein an output terminal of the USB hub module is connected to the USB plug, and a first input terminal of the USB hub module is connected to the keyboard control chip, and a second input terminal of the USB hub module is connected to the ADSL modem module, an input terminal of the signal separator is connected to the telephone interface, and a first output terminal of the signal separator is connected to the ADSL modem module, and a second output terminal of the signal separator is connected to the telephone module.

5. The keyboard of claim 1, further comprising a network plug, a signal separator configured to separate network connection from telephone connection, and an ADSL modem module, wherein an input terminal of the signal separator is connected to the telephone interface, and a first output terminal of the signal separator is connected to the ADSL modem module, and a second output terminal of the signal separator is connected to the telephone module, the network plug is connected to the ADSL modem module.

6. The keyboard of claim 1, further comprising an audible apparatus configured for outputting an audible signal, a receive/stop key configured for accept incoming telephone calls and disconnect from calls, a redial key configured for redialing last phone number entered, an headset interface configured for receiving a telephone headset, and a volume key configured for adjusting volume of the audible apparatus, wherein the telephone module are connected to the audible apparatus, the receive/stop key, the headset interface, the redial key, and the volume key.

7. The keyboard of claim 6, wherein the audible apparatus and the receive/stop key are mounted on top of the numerical keypad, the redial key is mounted on top of the numerical keypad, the volume key is set on a sidewall of the keyboard.

8. The keyboard of claim 6, wherein the audible apparatus is a buzzer.

9. The keyboard of claim 1, further comprising an indication apparatus connected to the telephone module for indicating a work state of telephone communication.

10. The keyboard of claim 9, wherein the indication apparatus is an indicator.

11. The keyboard of claim 9, wherein the indicator is located between the numerical keypad and the receive/stop key, the switch key is mounted on bottom of the numerical keypad, the telephone interface and the keyboard plug are set on a sidewall of the keyboard, the headset interface is set on another sidewall of the keyboard.
